(19) United States
(12) Patent Application Publication
(10) Pub. No.: US 2017/0042018 A1
(43) Pub. Date: Feb. 9, 2017

(54) Dual Layer Shielding Cover and Terminal

(71) Applicant: ZTE Corporation, Shenzhen (CN)

(72) Inventor: Yunyun LONG, Shenzhen (CN)

(21) Appl. No.: 15/106,339

(22) PCT Filed: Jun. 9, 2014
(86) PCT No.: PCT/CN2014/079541

§ 371 Date: Jun. 20, 2016

(30) Foreign Application Priority Data
Dec. 18, 2013 (CN) 201320838365.2

(51) Int. Cl. H05K 1/02; H05K 9/00; H05K 1/18; H05K 7/20

(52) U.S. Cl. CPC H05K 1/0203; H05K 7/20445; H05K 9/0032; H05K 1/18; H05K 2201/10371

(57) ABSTRACT

A dual layer shielding cover is provided and includes a dual layer structure with an upper layer shielding cover (22) and a lower layer shielding cover (21). The dual layer shielding cover is formed by stamping through a mould, for example, formed by bending and stretching, etc.

### TECHNICAL FIELD

The present disclosure relates to the field of electronic technologies, particularly to a dual layer shielding cover and a terminal.

### BACKGROUND

With the development of technologies of portable electronic devices and the mobile Internet, portable terminals tend to have close or identical functions and performance as those of a computer. The processing capability of terminals is also becoming more and more powerful and the uploading and downloading rates of wireless Internet access are also becoming increasingly higher. Accordingly, various chips in the terminal also have increasingly higher power consumption and more heat emission, and there is a sharp contradiction between heat emission and normal use of the device. Therefore, it is necessary to solve or alleviate the problem of heat dissipation in the terminal device.

At present, heat dissipation methods of the terminal device mainly include: heat conduction, heat storage and heat dissipation.

The heat conduction is a means that a heat dissipation material is added directly on a heat radiating chip of the terminal so as to accelerate heat conduction to the exterior, or a low temperature part and a high temperature part are connected by a heat dissipation material to conduct the heat of the high temperature area to a low temperature area so that the temperature of the whole terminal becomes uniform. However, there is still heat remained in the terminal during the heat conduction, and after the overall heat of the terminal is balanced, the temperature is easy to increase to an upper limit; and at the moment, it is necessary to decelerate running of the terminal or turn off some functions so as to reduce overall heat emission.

The heat storage is a means that a high heat storage material is filled by fully utilizing a structural gap in a limited space of the terminal, so as to transfer heat to the surface of the terminal more slowly, therefore, a user will not sense heat emission of the device in a relatively short period of time, thereby improving user experience during the heat emission.

The heat dissipation is means that a device for air circulation or liquid circulation is added in the terminal to dissipate and balance heat, which has powerful heat dissipation capability. However, it is difficult to form a circulating space in a limited space of the terminal, and such a solution can be hardly implemented.

Required by radiation shielding, it is necessary to shield some high speed signal devices on a Printed Circuit Board (PCB) so as to avoid interference on the performance of the terminal. Currently, the PCB is connected with a shielding cover by two methods. The first method is to weld a shielding bracket on the PCB and lock the shielding cover on the shielding bracket; and the other method is to integrally form a shielding bracket and the shielding cover through stamping using a mould, i.e. the shielding bracket and the shielding cover are directly welded on the PCB as a whole. Generally, a shielding cover in the related art is a single layer shielding bracket cover as shown in FIG. 1, including a main board PCB 10 and a single layer shielding cover 11. Although the shielding cover is made of a rigid material and has relatively good heat conductivity, the shielding cover on the PCB is a single layer shielding cover with limited heat dissipation effect.

### SUMMARY

In view of this, embodiments of the present disclosure provide a dual layer shielding cover and a terminal, capable of dissipating heat effectively.

An embodiment of the present disclosure provides a dual layer shielding cover, formed by a dual layer structure with an upper layer shielding cover and a lower layer shielding cover, wherein the dual layer shielding cover is formed by stamping through a mould.

In an exemplary embodiment, the dual layer shielding cover is formed by stamping through the mould in a bending way or stretching way.

In an exemplary embodiment, a size of the upper layer shielding cover is consistent with a size of the lower layer shielding cover.

In an exemplary embodiment, a size of the lower layer shielding cover is larger than a size of the upper layer shielding cover.

In an exemplary embodiment, a size of the lower layer shielding cover is smaller than or equal to a size of a PCB shielded by the dual layer shielding cover.

In an exemplary embodiment, an opening is arranged on the upper layer shielding cover.

In an exemplary embodiment, a location of the opening on the upper layer shielding cover corresponds to an area where a heat radiating device on the PCB shielded by the dual layer shielding cover locates.

In an exemplary embodiment, a heat dissipation material is arranged between the upper layer shielding cover and the lower layer shielding cover.

An embodiment of the present disclosure further provides a terminal, including a PCB provided with a chip and the dual layer shielding cover described above.

It can be learned from the technical solution above that a shielding cover of the embodiments of the present disclosure is a dual layer structure compared with the related art, thus greatly accelerating conduction of heat from a high temperature area to a low temperature area and accelerating heat balancing, so as to reduce the temperature of a local hotspot, and more effectively conduct heat onto the shielding cover.

Further, the dual layer shielding cover provided by the embodiments of the present disclosure is formed by stamping through a mould at low cost, in contrast, a heat dissipation material is 5-10 times more expensive than the shielding cover, thus the dual layer shielding cover largely saves cost.

### BRIEF DESCRIPTION OF THE DRAWINGS

FIG. 1 is a structural diagram of a shielding cover on a PCB in the related art;

FIG. 2 is a structural diagram of a dual layer shielding cover according to the first embodiment of the present disclosure;

FIG. 3 is a stereo structural diagram of FIG. 2;

FIG. 4 is a structural diagram of a dual layer shielding cover according to the second embodiment of the present disclosure;

FIG. 5 is a stereo structural diagram of FIG. 4;

FIG. 6 is a structural diagram of a dual layer shielding cover according to the third embodiment of the present disclosure; and

FIG. 7 is a structural diagram of a dual layer shielding cover according to the fourth embodiment of the present disclosure.

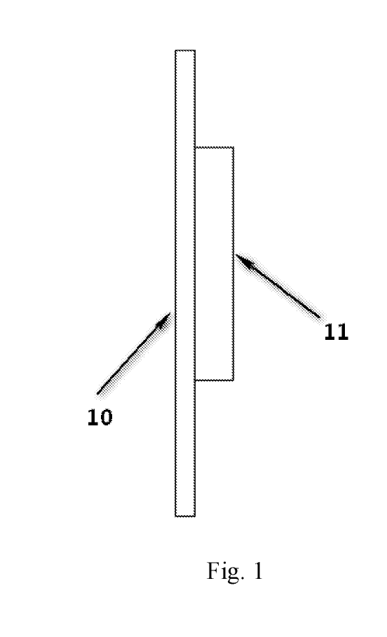

### DETAILED DESCRIPTION OF THE EMBODIMENTS

The embodiments of the present disclosure provide a dual layer shielding cover and a terminal so as to solve the technical problem that a single layer shielding cover on a PCB in the related art has poor heat dissipation performance.

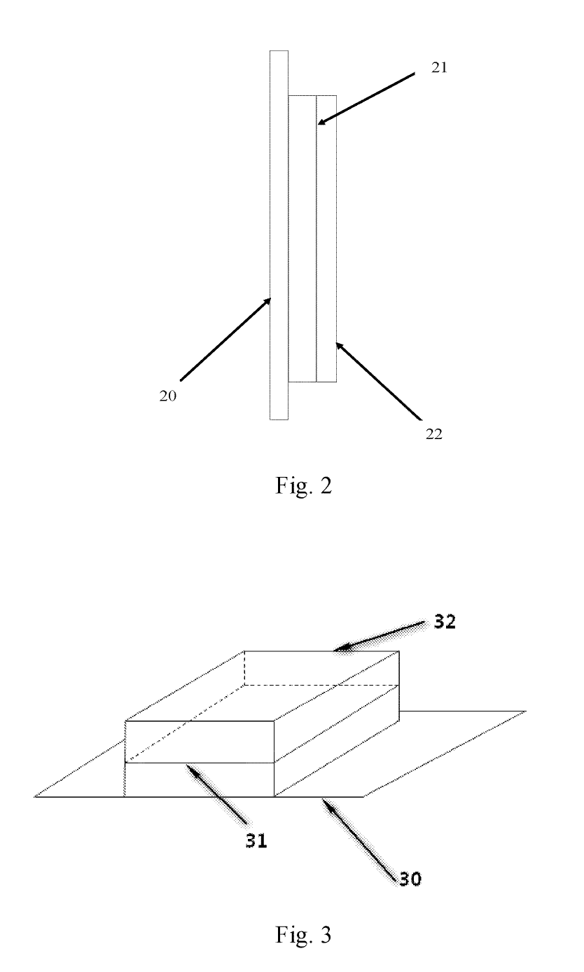

FIG. 2 is a structural diagram of a dual layer shielding cover according to the first embodiment of the present disclosure. As shown in FIG. 2, the first embodiment includes: a main board PCB 20, an upper layer shielding cover 22 and a lower cover shielding cover 21. The upper layer shielding cover and the lower layer shielding cover in the dual layer shielding cover have the same size. There may be air capable of insulating heat therebetween, thus greatly accelerating conduction of heat from a high temperature area to a low temperature area and accelerating heat balancing, so as to reduce the temperature of a local hotspot, and implement better heat dissipation effect compared with the related art.

The dual layer shielding cover may be formed by stamping through a mould, and the dual layer shielding cover may be formed by stamping through the mould in a bending way or stretching way.

FIG. 3 is a stereo structural diagram of FIG. 2, which describes the structure of the present design more clearly, including: a main board PCB 30, a lower layer shielding cover 31 and an upper layer shielding cover 32. The dual layer shielding cover fully utilizes a structural space, and fully utilizes the excellent heat conduction performance of a rigid material, which is beneficial for heat conduction so as to rapidly dissipate the heat to the whole terminal. In the meanwhile, air capable of insulating heat is provided between the lower layer shielding cover 31 and the upper layer shielding cover 32, thus well avoiding the problem of local over-temperature on the surface of the terminal.

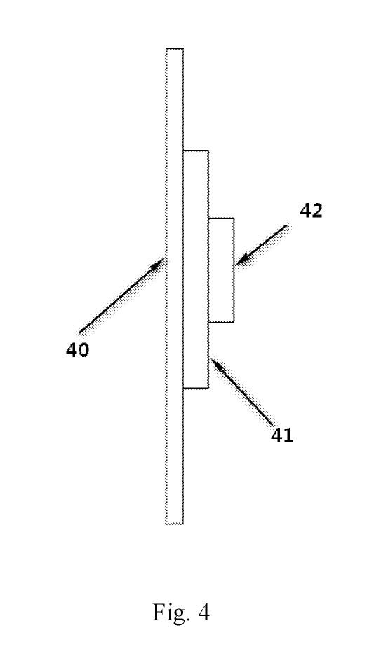

FIG. 4 is a structural diagram of a dual layer shielding cover according to the second embodiment of the present disclosure. As shown in FIG. 4, the second embodiment includes: a main board PCB 40, a lower layer shielding cover 41 and an upper layer shielding cover 42. The upper layer shielding cover 42 is added for major heat radiating sources, such a main chip and a power source chip on the main board PCB 40, and the upper layer shielding cover on the major heat radiating sources also has a heat insulating function, thus avoiding local overheat on the surface of the terminal, and there is air between the upper layer shielding cover and the lower layer shielding cover.

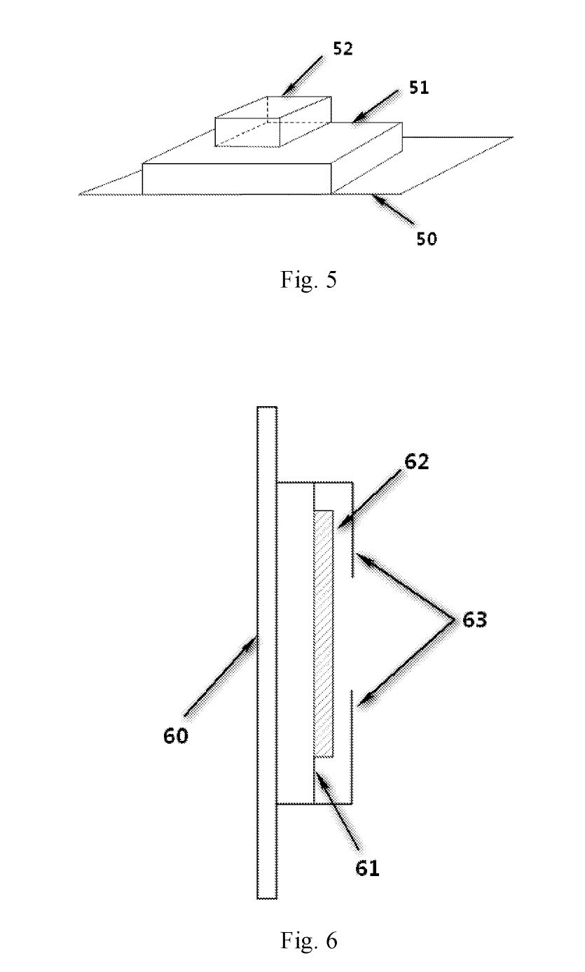

FIG. 5 is a stereo structural diagram of FIG. 4, which describes the structure of the present design more clearly, including: a main board PCB 50, a lower layer shielding cover 51 and an upper layer shielding cover 52. The upper layer shielding cover 52 locates above major heat radiating sources, such as a main chip and a power source chip on the main board PCB 50.

FIG. 6 is a structural diagram of a dual layer shielding cover according to the third embodiment of the present disclosure. As shown in FIG. 6, the third embodiment includes: a main board PCB 60, a lower layer shielding cover 61, an upper layer shielding cover 63 with an opening, and a heat dissipation material 62 arranged between the two layers of shielding covers. The solution fully utilizes the excellent heat dissipation performance of a rigid material on one hand. In the meanwhile, an additional heat dissipation material is adhered between the two layers of shielding covers, so as to rapidly conduct heat onto an adjacent component, thus rapidly conducting the heat onto the surface of the terminal and accelerating heat balancing.

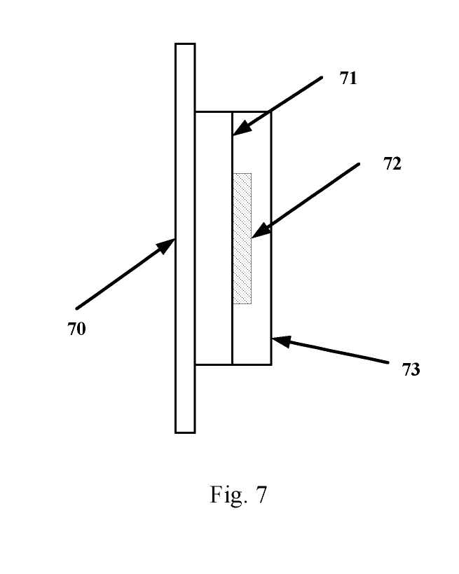

FIG. 7 is a structural diagram of a dual layer shielding cover according to the fourth embodiment of the present disclosure. As shown in FIG. 7, the fourth embodiment includes: a main board PCB 70, a lower layer shielding cover 71, an upper layer shielding cover 73 and a heat dissipation material 72 adhered between the two layers of shielding covers, wherein the upper layer shielding cover is not opened, and has a size equal to that of the lower layer shielding cover.

A dual layer shielding cover in the embodiments above may be formed by stamping through a mound, including different methods such as forming by bending and forming by stretching, etc.

A heat dissipation material in the embodiments above may be graphite, heat conduction silica gel and so on.

It needs to be noted that a dual layer shielding cover in the present disclosure also needs to be mounted by using a shielding bracket. For example, a method is to weld the shielding bracket on a PCB, and lock the shielding cover on the shielding bracket and another method is to integrally form the shielding bracket and the shielding cover by stamping through a mound, i.e. the shielding bracket and the shielding cover are directly welded on a PCB as a whole.

The above are only specific embodiments centralized in the present disclosure. Theoretically, a shielding cover may be provided with three layers, four layers, or even more layers. However, the shielding cover is provided with two or three layers preferably in consideration of the problem of the volume of a mobile phone. Of course, the present disclosure may be also implemented by various other ways. Those skilled in the art may make various corresponding changes and variations according to the present disclosure without departing from the principle of the present disclosure, and all these corresponding changes and variations should belong to the protection scope of the appended claims of the present disclosure.

### INDUSTRIAL APPLICABILITY

A dual layer shielding cover of the embodiments of the present disclosure is formed by a dual layer structure with an upper layer shielding cover and a lower layer shielding cover, wherein the dual layer shielding cover is formed by stamping through a mould. The shielding cover of the embodiments of the present disclosure is a dual layer structure compared with the related art, thus greatly accelerating conduction of heat from a high temperature area to a low temperature area and accelerating heat balancing, so as to reduce the temperature of a local hotspot, and more effectively conduct heat onto the shielding cover.

What is claimed is:

1. A dual layer shielding cover, formed by a dual layer structure with an upper layer shielding cover and a lower layer shielding cover, wherein the dual layer shielding cover is formed by stamping through a mould.

2. The dual layer shielding cover as claimed in claim 1, wherein the dual layer shielding cover is formed by stamping through the mould in a bending way or stretching way.

3. The dual layer shielding cover as claimed in claim 1, wherein a size of the upper layer shielding cover is consistent with a size of the lower layer shielding cover.

4. The dual layer shielding cover as claimed in claim 1, wherein a size of the lower layer shielding cover is larger than a size of the upper layer shielding cover.

5. The dual layer shielding cover as claimed in claim 1, wherein a size of the lower layer shielding cover is smaller than or equal to a size of a Printed Circuit Board (PCB) shielded by the dual layer shielding cover.

6. The dual layer shielding cover as claimed in any one of claims 1 to 5, wherein an opening is arranged on the upper layer shielding cover.

7. The dual layer shielding cover as claimed in claim 6, wherein a location of the opening on the upper layer shielding cover corresponds to an area where a heat radiating device on the PCB shielded by the dual layer shielding cover locates.

8. The dual layer shielding cover as claimed in claim 7, wherein a heat dissipation material is arranged between the upper layer shielding cover and the lower layer shielding cover.

9. A terminal, comprising a Printed Circuit Board (PCB) provided with a chip and the dual layer shielding cover as claimed in any one of claims 1 to 8.
